(19) United States
(12) Patent Application Publication
(10) Pub. No.: US 2003/0116846 A1
(43) Pub. Date: Jun. 26, 2003

(54) Stacked structure of a ball grid array (BGA) integrated circuit package

(76) Inventors: Nai Hua Yeh, Hsinchu Hsien (TW); Chen Pin Peng, Hsinchu Hsien (TW); Rong Fong Ding, Hsinchu Hsien (TW); Hsiu Wen Tu, Hsinchu Hsien (TW); Mon Nan Ho, Hsinchu Hsien (TW)

Correspondence Address: Keith Kline, PRO-TECHTOR INTERNATIONAL SERVICES, 20775 Norada Court, Saratoga, CA, 95070-3018, US

(21) Appl. No.: 10/027,539

(22) Filed: Dec. 20, 2001

(51) Int. Cl. H01L 29/93

(52) U.S. Cl. 257/739

(57) ABSTRACT

A stacked structure of a BGA (Ball Grid Array) integrated circuit package arranged on a printed circuit board includes a lower IC package body, an upper IC package body and glue. The lower IC package body has a first surface and a second surface opposite to the first surface. The first surface is formed with a plurality of first contacts for electrically connecting to the printed circuit board. The second surface is formed with a plurality of second contacts for electrically connecting to the upper IC package body. The upper IC package body is stacked above the lower IC package body and electrically connected to the second contacts on the second surface of the lower IC package body. The glue is provided between the lower IC package body and the upper IC package body for covering and protecting the plurality of second contacts.

### BACKGROUND OF THE INVENTION

1. Field of the Invention

The invention relates to a stacked structure of a ball grid array (BGA) integrated circuit package, in particular, to an integrated circuit package capable of protecting the BGA metallic balls to obtain better signal transmission effects.

2. Description of the Related Art

Referring to FIG. 1, the conventional stacked structure of a BGA integrated circuit (IC) package includes a lower IC package body 10 and an upper IC package body 12 stacked on the lower IC package body 10.

The lower IC package body 10 includes a substrate 14, an integrated circuit 16, a plurality of wires 18 and a plurality of BGA metallic balls 20. The lower surface 22 of the substrate 14 is formed with first contacts 24 while the upper surface 26 of the substrate 14 is formed with second contacts 28. The integrated circuit 16 is provided on the upper surface 26 of the substrate 14 and is electrically connected to the substrate 14 via the plurality of wires 18. The plurality of metallic balls 20 are placed under the first contact 24 of the substrate 14 for electrically connecting to the printed circuit board 30.

The upper IC package body 12 is stacked above the upper surface 26 of the substrate 14 of the lower IC package body 10. A plurality of metallic balls 32 are arranged on the upper surface 26 of the substrate 14 for electrically connecting to the second contacts 28 of the upper surface 26 of the substrate 14. Thus, the upper and lower IC package bodies 12 and 10 form a stacked structure.

In the above-mentioned stacked structure of the integrated circuit package, since the plurality of metallic balls 32 of the upper IC package body 12 are exposed to the outside, the metallic balls 32 may be easily damaged.

In view of the above-mentioned problem, it is an important subject matter for the prevent inventor to provide a stacked structure of a BGA integrated circuit package in which the BGA metallic balls of the stacked IC package bodies are sealed to protect the BGA metallic balls. Thus, the metallic ball can not be easily damaged and the lifetime of the integrated circuit package can be lengthened.

### SUMMARY OF THE INVENTION

It is therefore an object of the invention to provide a stacked structure of a BGA integrated circuit package capable of protecting the BGA metallic balls after the integrated circuits are stacked.

It is another object of the invention to provide a stacked structure of a BGA integrated circuit package capable of protecting the BGA metallic balls and the integrated circuits by way of glue pouring after the integrated circuit package bodies are stacked. In this case, it is convenient for the manufacturing processes to be performed.

To achieve the above-mentioned objects, a stacked structure of a BGA (Ball Grid Array) integrated circuit package arranged on a printed circuit board includes a lower IC package body, an upper IC package body and glue. The lower IC package body has a first surface and a second surface opposite to the first surface. The first surface is formed with a plurality of first contacts for electrically connecting to the printed circuit board. The second surface is formed with a plurality of second contacts for electrically connecting to the upper IC package body. The upper IC package body is stacked above the lower IC package body and electrically connected to the second contacts on the second surface of the lower IC package body. The glue is provided between the lower IC package body and the upper IC package body for covering and protecting the plurality of second contacts.

According to the above-mentioned stacked structure of the integrated circuit package, the contacts in the integrated circuit package bodies can be protected by the glue. Thus, the contacts are free from being damaged, and the lifetime of the integrated circuit package can be lengthened.

### BRIEF DESCRIPTION OF THE DRAWINGS

These and other objects and advantages of the present invention will become apparent by reference to the following description and accompanying drawings wherein:

FIG. 1 is a schematic illustration showing a conventional stacked structure of a BGA integrated circuit package;

FIG. 2 is a schematic illustration showing a stracked structure of a BGA integrated circuit package according to the invention;

FIG. 3 shows a first illustration embodying a stracked structure of a BGA integrated circuit package according to the invention; and

FIG. 4 shows a second illustration embodying a stracked structure of a BGA integrated circuit package according to the invention.

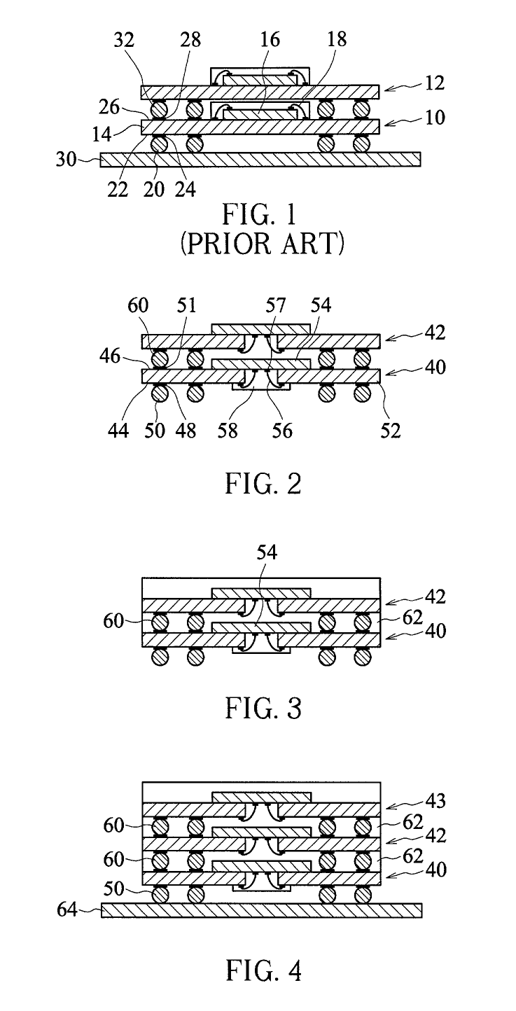

### DETAIL DESCRIPTION OF THE INVENTION

Referring to FIG. 2, the stacked structure of a BGA integrated circuit package in accordance with an embodiment of the invention includes a lower IC package body 40 and an upper IC package body 42. The lower IC package body 40 has a first surface 44 and a second surface 46 opposite to the first surface 44. The first surface is formed with a plurality of first contacts 48 under which a plurality of BGA metallic balls 50 are formed. The second surface 46 is formed with a plurality of second contacts 51 for electrically connecting to the upper IC package body 42.

In this embodiment, the lower IC package body 40 includes a substrate 52, an integrated circuit 54 and a plurality of wires 56. The substrate 52 is formed with a cavity 58. The integrated circuit 54 is placed on the substrate 52 and formed with a plurality of bonding pads 57 exposed to the outside from the cavity 58. The plurality of wires 56 are arranged within the cavity 58 for electrically connecting the integrated circuit 54 to the first contacts 48 of the substrate 52.

The upper IC package body 42 is stacked above the second surface 46 of the lower IC package body 40, and the BGA metallic balls 60 under the upper IC package body 42 are electrically connected to the second contacts 51 of the lower IC package body 40. Thus, the stacked combination of the upper and lower IC package bodies 42 and 40 are completed. In this embodiment, the upper IC package body 42 and the lower IC package body 40 have the same structure. That is, each of the upper and lower IC package bodies 42 and 40 includes a substrate 52, an integrated circuit 54 and a plurality of wires 56. The substrate 52 is formed with a cavity 58. The integrated circuit 54 is arranged on the substrate 52. The plurality of bonding pads 57 under the substrate 52 are exposed to the outside from the cavity 58. The plurality of wires 56 are arranged within the cavity 58 for electrically connecting the integrated circuit 54 to the first contacts 48 of the substrate 52.

Referring to FIG. 3, after the upper and lower IC package bodies 42 and 40 are stacked as shown in FIG. 2, glue 62 is filled between the upper IC package body 42 and the lower IC package body 40 by way of glue pouring. Thus, the integrated circuit 54 and the BGA metallic balls 60 for electrically connecting to the upper and lower IC package bodies 42 and 40 are sealed by the glue 62. In this case, it is possible to prevent the integrated circuit 54 and the BGA metallic balls 60 from being damaged by external factors. The lifetime of the stacked integrated circuit package is not adversely influenced. Also, in the sealing process, the integrated circuit 54 can be sealed and protected.

Referring to FIG. 4, a plurality of integrated circuit package bodies 40, 42 and 43 are stacked in order, and glue 62 is poured between adjacent IC package bodies. In this case, the BGA metallic balls 60 can be protected. The BGA metallic balls 50 of the lower IC package body 40 are used for electrically connecting to a printed circuit board 64. Thus, the signals from the plurality of IC package bodies 40, 42 and 43 can be transmitted to the printed circuit board 64.

According to the above-mentioned structure, the stacked BGA integrated circuit package has the following advantages.

1. After the plurality of BGA integrated circuit package bodies are stacked, the BGA metallic balls can be protected from being damaged.

2. After the integrated circuit package bodies are stacked, the BGA metallic balls and the integrated circuits can be sealed and protected by way of glue pouring, which is convenient in the manufacturing processes.

While the invention has been described by way of examples and in terms of preferred embodiments, it is to be understood that the invention is not limited to the disclosed embodiments. To the contrary, it is intended to cover various modifications. Therefore, the scope of the appended claims should be accorded the broadest interpretation so as to encompass all such modifications.

What is claimed is:

1. A stacked structure of a BGA (Ball Grid Array) integrated circuit package arranged on a printed circuit board, comprising:
a lower IC package body having a first surface and a second surface opposite to the first surface, the first surface being formed with a plurality of first contacts for electrically connecting to the printed circuit board, and the second surface being formed with a plurality of second contacts;
an upper IC package body stacked above the lower IC package body and electrically connected to the second contacts on the second surface of the lower IC package body; and
glue provided between the lower IC package body and the upper IC package body for covering the plurality of second contacts.

2. The stacked structure of the BGA integrated circuit package according to claim 1, wherein the first contacts and the second contacts of the lower IC package body are formed with a plurality of BGA metallic balls.

3. The stacked structure of the BGA integrated circuit package according to claim 1, wherein the lower IC package body comprises a substrate formed with a cavity, an integrated circuit arranged on the substrate, and a plurality of wires arranged within the cavity for electrically connecting the integrated circuit to the substrate.

4. The stacked structure of the BGA integrated circuit package according to claim 1, wherein the upper IC package body comprises a substrate formed with a cavity, an integrated circuit arranged on the substrate, and a plurality of wires arranged within the cavity for electrically connecting the integrated circuit to the substrate.

5. The stacked structure of the BGA integrated circuit package according to claim 1, wherein the glue is filled between the lower IC package body and the upper IC package body by way of glue pouring.
